(19) United States
(12) Patent Application Publication
(10) Pub. No.: US 2015/0187981 A1
(43) Pub. Date: Jul. 2, 2015

(54) Method for Deposition

(71) Applicant: First Solar, Inc., Tempe, AZ (US)

(72) Inventors: Bastiaan Arie Korevaar, Schenectady, NY (US); Roman Shuba, Albany, CA (US)

(73) Assignee: FIRST SOLAR, INC., Tempe, AZ (US)

(21) Appl. No.: 14/640,595

(22) Filed: Mar. 6, 2015

Related U.S. Application Data
(62) Division of application No. 13/285,501, filed on Oct. 31, 2011.

(51) Int. Cl. H01L 31/18

(52) U.S. Cl. CPC H01L 31/1828

(57) ABSTRACT

Embodiments of the present invention include a method. The method includes producing a first vapor from a solid source material, reacting hydrogen telluride to form a second vapor comprising tellurium, and depositing on a support a coating material comprising tellurium within a deposition environment, the deposition environment comprising the first vapor and the second vapor. Another embodiment is a system. The system includes a deposition chamber disposed to contain a deposition environment in fluid communication with a support; a solid source material disposed in fluid communication with the deposition chamber; and a hydrogen telluride source in fluid communication in fluid communication with the deposition chamber.

### BACKGROUND

This invention generally relates to deposition of films that include tellurium. More particularly, this invention relates to the use of hydrogen telluride as a source of tellurium during deposition processes.

Thin film solar cells or photovoltaic devices typically include a plurality of semiconductor layers disposed on a support, wherein one layer serves as a window layer and a second layer serves as an absorber layer. The window layer allows the penetration of solar radiation to the absorber layer, where the optical energy is converted to usable electrical energy. Cadmium telluride/cadmium sulfide (CdTe/CdS) heterojunction-based photovoltaic cells are one such example of thin film solar cells.

Cadmium telluride (CdTe)-based photovoltaic devices typically demonstrate comparatively low power conversion efficiencies with respect to other photovoltaic devices; this characteristic may be attributed to a relatively low open circuit voltage (V_{oc}) in relation to the band gap of the material which is due, in part, to the low effective carrier concentration and short minority carrier lifetime in CdTe. Effective carrier concentration of CdTe, with associated increase in open circuit voltage, may be improved by doping with p-type dopants. However, doping CdTe with p-type dopants to desirable carrier concentration levels has proved difficult.

Thus, there is a need for improved methods of making photovoltaic devices having doped absorber layers with higher carrier densities, resulting in higher efficiencies.

### BRIEF DESCRIPTION OF THE DRAWINGS

These and other features, aspects, and advantages of the present invention will become better understood when the following detailed description is read with reference to the accompanying drawings in which like characters represent like parts throughout the drawings, wherein:

FIG. 1 is a schematic of one example of a system in accordance with certain embodiments presented herein; and

FIG. 2 is a schematic representation of one example of coating layers deposited in accordance with certain embodiments presented herein.

### BRIEF DESCRIPTION OF THE INVENTION

Embodiments of the present invention are provided to meet these and other needs. One embodiment is a method. The method includes producing a first vapor from a solid source material, reacting hydrogen telluride to form a second vapor comprising tellurium, and depositing on a support a coating material comprising tellurium within a deposition environment, the deposition environment comprising the first vapor and the second vapor. One particular example of the method includes disposing a first layer comprising oxygenated cadmium telluride over a support, producing a first vapor comprising cadmium and tellurium from a solid source material, reacting hydrogen telluride to form a second vapor comprising tellurium, and depositing on the support a coating material comprising cadmium, tellurium, and oxygen within a deposition environment that includes oxygen, the first vapor, and the second vapor.

Another embodiment is a system. The system includes a deposition chamber disposed to contain a deposition environment in fluid communication with a support; a solid source material disposed in fluid communication with the deposition chamber; and a hydrogen telluride source in fluid communication in fluid communication with the deposition chamber.

### DETAILED DESCRIPTION

As discussed in detail below, some of the embodiments of the present invention include methods and systems for depositing materials, including methods and systems for making a photovoltaic device.

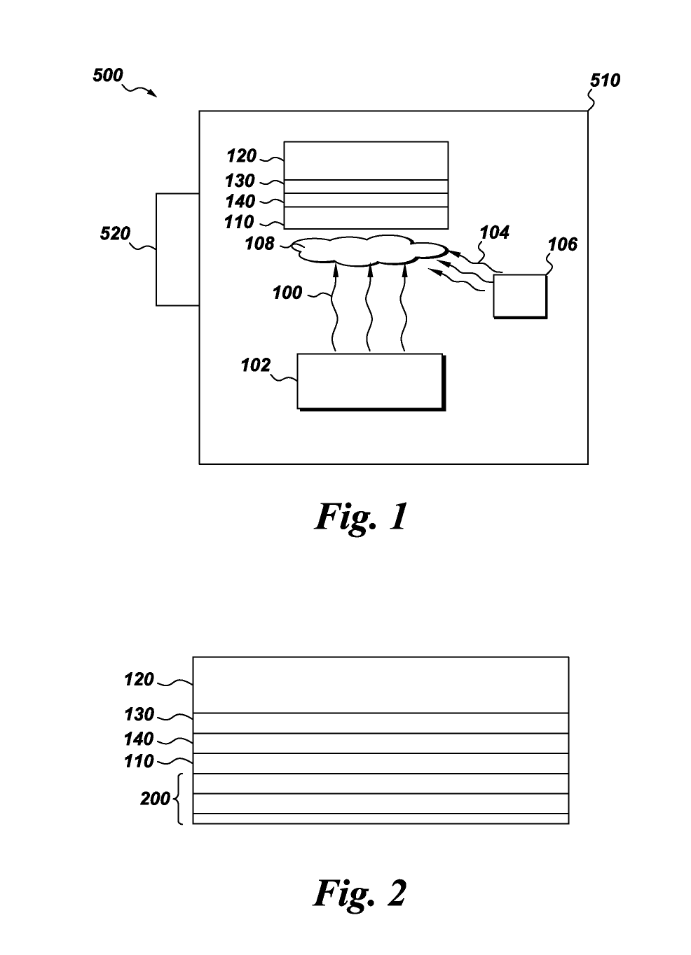

Referring to FIG. 1, in one embodiment a method comprises producing a first vapor 100 from a solid source material 102. Source 102 in some embodiments comprises cadmium and tellurium, and in some embodiments is cadmium telluride material of a type typically used in physical vapor deposition methods for depositing tellurium-containing semiconductors like, for example, cadmium telluride films. First vapor 100 may be produced by any of several methods, an example of which includes heating source material 102. Such heating may be used to sublime or otherwise produce vapor 100 from source 102. Another example of producing vapor 100 includes sputtering the source 102 to eject material from source 102 into vapor 100.

The method further comprises reacting hydrogen telluride (H₂Te) to form a second vapor 104. Second vapor 104 comprises tellurium. In one embodiment, this reacting step includes decomposing hydrogen telluride by thermal or other means into its constituents or into species containing its constituents. In other embodiments, this reacting step includes reacting hydrogen telluride with oxygen, for example according to the reaction

2H₂Te+O₂→2H₂O+2Te (Equation 1);

in which the tellurium becomes incorporated into second vapor 104. The oxygen may be supplied from source 102 or from another oxygen source (not shown). The hydrogen telluride is supplied from a hydrogen telluride source 106. In one embodiment, source 106 is a direct source of hydrogen telluride, such as a tank containing gas that includes hydrogen telluride. In another embodiment, source 106 includes a precursor material of hydrogen telluride, such as a telluride salt. Thus, some embodiments of the method described herein include a step of reacting the precursor material to form the hydrogen telluride. One example of a suitable precursor material is ammonium telluride, which at temperatures greater than approximately 80 degrees Celsius may be decomposed to form vapors of ammonia and hydrogen telluride. Thus, in one embodiment, reacting the precursor material includes heating the precursor material. The heating or other method of reacting the precursor material may be performed at the source 106, or within a deposition environment 108 (see below).

First vapor 100 and second vapor 104 are fed into deposition environment 108 so that environment 108 includes both vapors 100, 104. A coating material 110 is deposited within deposition environment 108. Environment 108 may further include other vapors, such as inert gases including, for example, helium and/or argon. The deposition of coating material 110 occurs on a support 120. Support 120 may include any suitable material. Particular examples include glass, metal, or plastic materials. In one embodiment, support 120 comprises glass, such as soda-lime glass or borosilicate glass. Deposition of coating material 110 may be performed in any suitable configuration associated with the particular deposition process selected by the operator. Examples of deposition processes include, without limitation, close-space sublimation, sputtering (deposition of sputtered material), vapor transport deposition, diffuse transport deposition, or combinations or variations of these techniques. Suitable temperatures, pressures, and other process parameters used in embodiments of the method described herein will thus depend in part on the method and configuration of deposition used; selection of these methods and their associated process parameters will be within the understanding of one skilled in the art with the aid of this disclosure.

In one embodiment, environment 108 includes oxygen. The oxygen may be present, for instance, due to its use in reacting with the hydrogen telluride as described above. Alternatively, oxygen may be supplied directly to environment 108. In some embodiments, oxygen is present in environment 108 in an effective concentration sufficient to become incorporated into coating material 110 at concentrations above 10¹⁷ cm⁻³. The amount of oxygen supplied to environment 108 will depend in part on the method of deposition used. For instance, where deposition of coating material 110 includes close-space sublimation, approximately 1 Torr (133 Pascal) of oxygen may be used to incorporate oxygen into coating material 110.

The composition of coating material 110 depends in part on the composition of source material 102 and deposition environment 108. Coating 110 comprises tellurium due to the presence of tellurium in deposition environment 108 via second vapor 104. Tellurium may also be supplied to deposition environment 108 from solid source material 102. In some embodiments, coating material 110 comprises a telluride. In certain embodiments, coating 110 further comprises cadmium, and in particular embodiment, coating 110 comprises cadmium telluride. As used herein, “cadmium telluride” includes tellurides that comprise cadmium but also may comprise certain other elements, such as zinc, manganese, magnesium, or combinations including any of these. as dopants or as partial substitutes for cadmium in the telluride compound. In some embodiments, coating material 110 includes oxygenated cadmium telluride, in which the cadmium telluride includes dissolved oxygen in a range from about 10¹⁷ cm⁻³ to about 10¹⁹ cm⁻³.

Support 120, in some embodiments, includes one or more layers 130, over which coating material 110 is deposited. Layers 130 may include, for example, a contact layer (such as a metal, or a transparent conductive oxide, of which cadmium tin oxide is one example), a buffer layer (such as zinc tin oxide), and/or a window layer (such as a semiconducting layer, for example an n-type cadmium sulfide, forming a heterojunction with coating material 110). In one embodiment, layer 130 includes a first layer 140 such that coating material 110 is disposed over the first layer 140. As used herein, the term “first” is only used to denote the position of first layer 140 relative to coating material 110 and does not preclude the existence of other layers 130 interposed between support 120 and first layer 140.

In one embodiment, first layer 140 comprises cadmium and tellurium. In certain embodiments, first layer comprises cadmium, tellurium, and oxygen. In particular embodiments, the method described above further comprises depositing first layer 140 in an initial environment that is essentially free of second vapor 104. The initial environment may, however, include other inert gases such as helium and/or argon. As noted above in Equation 1, the reaction of hydrogen telluride with oxygen may form water vapor, which may be detrimental to photovoltaic device performance if incorporated at an interface between other layers 130 (such as a window layer) and coating material 110. Thus, in this embodiment, deposition of material is initially performed without use of hydrogen telluride, but once first layer 140 has been deposited to a desired thickness, such as (depending in part on the desired application and methods for deposition of the film) up to 500 nm, up to 200 nm, or up to 100 nm, the hydrogen telluride is supplied to the process in accordance with the above description. Deposition of first layer 140 may be done in a separate deposition chamber (not shown) to maintain an environment free of water vapor, or in some embodiments it may be done in the same chamber as deposition of coating material 110. It will be apparent to those skilled in the art that, in some embodiments, particularly in “substrate configured” device designs in which a window layer is disposed after, rather than before, deposition of coating material 110, that the deposition of absorber material in an environment free of water vapor would occur after deposition of coating material 110, thereby disposing a subsequent layer 200 (FIG. 2) that has the compositional and structural features described above for first layer 140. It is the function of first layer 140, or, if device architecture dictates, a subsequent layer 200 (if this layer 200 is processed according to the description for layer 140, above) to separate the interface between coating material 110 and a window layer and to maintain an absorber layer/window layer interface that is essentially free of water vapor. It will be noted that telluride layers disposed in an environment substantially free of the hydrogen telluride vapor or its byproducts will have lower p-type doping due to the relatively lower tellurium content of the deposition environment.

In an illustrative embodiment, a method in accordance with the above description comprises disposing a first layer 140 comprising oxygenated cadmium telluride over a support 120; producing a first vapor 100 comprising cadmium and tellurium from a solid source material 102; reacting hydrogen telluride to form a second vapor 104 comprising tellurium; and depositing on support 120 a coating material 110 comprising cadmium, tellurium, and oxygen within a deposition environment 108. Environment 108 comprises oxygen, first vapor 100, and second vapor 104. Disposing first layer 140, in some embodiments, is performed in an initial environment that is essentially free of second vapor, as noted previously.

The use of hydrogen telluride as described above may provide certain embodiments of the method with an opportunity to incorporate levels of tellurium in deposition environment 108 that are in excess of the level needed to deposit stoichiometric cadmium telluride, and thus the coating material 110 may include excess tellurium. The excess tellurium may provide the coating material 110 with a higher p-type carrier concentration, such as greater than 5×10¹⁴ cm⁻³, or greater than 10¹⁵ cm⁻³, or even higher in some embodiments, such as 10¹⁶ cm⁻³, than is normally achieved by conventional deposition methods. Thus coating material 110 may be advantageously applied as an absorber material in photovoltaic devices, where the comparatively high carrier concentration may provide the device with higher open circuit potential than conventionally deposited material.

In some embodiments, the method described above further includes deposition of materials subsequent to the deposition of coating material 110. Referring to FIG. 2, some embodiments further include depositing one or more additional layers 200 on coating material 110. The nature of these additional layers 200 depends on the nature of the intended final product. For example, where the product is intended to be a photovoltaic device in a superstrate configuration, a transparent support 120 is used, and additional layers 200 may include back contact material. Where the product is intended to be a photovoltaic device in a substrate configuration, additional layers 200 may include a window layer and a front contact material. Moreover, as noted above, in substrate configurations, additional layers 200 may further include, in addition to a window layer, a layer deposited in the same manner described previously for first layer 140; that is, disposed in an environment essentially free of second vapor 104, to separate coating material 110 from a subsequently deposited window layer.

Other embodiments of the present invention include a system for coating deposition. Referring to FIG. 1, system 500 includes a solid source material 102 and a hydrogen telluride source 106. Both sources 102, 106 are in fluid communication with a deposition chamber 510. Deposition chamber 510 is disposed to contain a deposition environment 108 in fluid communication with a support 120; typically a pump (not shown) is employed to produce within chamber 510 vacuum conditions commonly applied in the physical deposition methods described above. Operation of system 500 is in accordance with the method described above. In certain embodiments, system 500 further comprises an oxygen source 520 in fluid communication with either the deposition chamber 510 or the hydrogen telluride source 106, so as to supply oxygen for reaction with hydrogen telluride, for incorporation into a material deposited with deposition chamber 510, or for both of these functions. System 500 may include other features not shown in the figure but that would be apparent to those skilled in the art with the aid of this disclosure. For example, multiple deposition chambers, or simply multiple deposition zones within chamber 510, may be added to allow for deposition steps to occur in different environments. Moreover, system 500 may further include the necessary conveyance mechanisms, such as drive trains, belts, and/or motors, to allow for transfer of support 120 into and out of deposition environment 108. Various heaters may be employed to heat either or both sources 102, 106. Mass flow controllers of the type commonly employed in the art are suitable for controlling the composition of deposition environment 108 during operation. Such features, and others, are commonly applied to coating deposition systems and methods to assist in scale-up and commercialization, and their application to system 500 is considered to be within the scope of this description. While only certain features of the invention have been illustrated and described herein, many modifications and changes will occur to those skilled in the art. It is, therefore, to be understood that the appended claims are intended to cover all such modifications and changes as fall within the true spirit of the invention.

1. A method comprising:
producing a first vapor from a solid source material;
reacting hydrogen telluride to form a second vapor comprising tellurium;
depositing on a support a coating material comprising tellurium within a deposition environment, the deposition environment comprising the first vapor and the second vapor.

2. The method of claim 1, wherein the solid source material comprises cadmium and tellurium.

3. The method of claim 1, wherein depositing the coating material comprises depositing the coating material via close-space sublimation, sputtering, vapor transport deposition, diffuse transport deposition, or a combination of any of the preceding.

4. The method of claim 1, wherein the coating material further comprises cadmium.

5. The method of claim 1, wherein the coating material comprises cadmium telluride.

6. The method of claim 1, wherein the deposition environment further comprises oxygen.

7. The method of claim 1, wherein reacting comprises reacting hydrogen telluride with oxygen.

8. The method of claim 1, further comprising reacting a precursor material to form the hydrogen telluride.

9. The method of claim 8, wherein the precursor material comprises a telluride salt.

10. The method of claim 8, wherein the precursor material comprises ammonium telluride.

11. The method of claim 8, wherein reacting the precursor material comprises heating the precursor material.

12. The method of claim 1, wherein the support comprises a first layer disposed on the support and wherein depositing the coating material on the support comprises depositing the coating material over the first layer.

13. The method of claim 12, wherein the first layer comprises cadmium, tellurium, and oxygen.

14. The method of claim 13, further comprising depositing the first layer on the support in an initial environment essentially free of the second vapor.

15. The method of claim 12, wherein the initial environment comprises cadmium, tellurium, and oxygen.

16. A method comprising:
disposing a first layer comprising oxygenated cadmium telluride over a support;
producing a first vapor comprising cadmium and tellurium from a solid source material;
reacting hydrogen telluride to form a second vapor comprising tellurium; and
depositing on the support a coating material comprising cadmium, tellurium, and oxygen within a deposition environment, the deposition environment comprising oxygen, the first vapor, and the second vapor.
